(19) United States
(12) Patent Application Publication
(10) Pub. No.: US 2024/0404985 A1
(43) Pub. Date: Dec. 5, 2024

(54) SEMICONDUCTOR CHIP BONDING DEVICE

(71) Applicant: SAMSUNG ELECTRONICS CO., LTD., SUWON-SI (KR)

(72) Inventor: BONGKEN YU, Suwon-si (KR)

(21) Appl. No.: 18/641,710

(22) Filed: Apr. 22, 2024

(30) Foreign Application Priority Data
Jun. 5, 2023 (KR) 10-2023-0072431

(51) Int. Cl. H01L 23/00

(52) U.S. Cl. CPC H01L 24/75; H01L 2224/751; H01L 2224/75824; H01L 2924/40

(57) ABSTRACT

A semiconductor chip bonding device may include a substrate support, a bonding head moveable in a first direction toward the substrate support, and a sealing member disposed on the bonding head and surrounding a circumferential surface of the bonding head and extending in the first direction from the bonding head toward the substrate support and movable in the first direction.

### CROSS-REFERENCE TO RELATED APPLICATION

This application claims priority to and the benefit of Korean Patent Application No. 10-2023-0072431 filed in the Korean Intellectual Property Office on Jun. 5, 2023, the contents of which are herein incorporated by reference in their entirety.

### BACKGROUND OF THE INVENTION

### (a) Technical Field

The present disclosure relates to a semiconductor package, and more particularly, to a semiconductor chip bonding device.

### (b) Discussion of Related Art

In a process of manufacturing a semiconductor package, a bonding process may be used for bonding a substrate and a semiconductor chip together, or for bonding between stacked semiconductor chips. For example, in a chip-on-wafer (CoW) process, a pad of a semiconductor chip and a pad of a wafer may be bonded by a thermal compression bonding process using heat, solder, and a non-conductive film (NCF).

In the thermal compression bonding process, bonding between the pad of the semiconductor chip and the pad of the wafer may be performed using a bonding head. In the bonding process, a non-conductive film (NCF) fillet may be freely formed. Accordingly, when semiconductor chips are stacked, the size of the NCF fillets may vary depending on the number of stacked semiconductor chips, and the exposed NCF fillets may be cut to produce the semiconductor package.

### SUMMARY OF THE INVENTION

The present disclosure attempts to provide a semiconductor chip bonding device capable of controlling a shape of a non-conductive film fillet. The present disclosure attempts to provide a semiconductor chip bonding device capable of forming non-conductive film fillets having a same shape and size.

According to an embodiment of the present disclosure, a semiconductor chip bonding device, which may include a substrate support, a bonding head moveable in a first direction toward the substrate support, and a sealing member disposed on the bonding head and surrounding a circumferential surface of the bonding head and extending in the first direction from the bonding head toward the substrate support and movable in the first direction. In an embodiment, the sealing member may include an upper sealing member disposed on the bonding head, and a lower sealing member extending from the upper sealing member and movable in the first direction independent of the upper sealing member, wherein the upper sealing member accommodates and supports at least a portion of the lower sealing member.

In an embodiment, a height of the lower sealing member may be at least about 1.2 times greater than a heights of a semiconductor chip disposed on the bonding head and a non-conductive film disposed below the semiconductor chip. In an embodiment, a height of the lower sealing member may be in a range of about 50 to 120 μm.

In an embodiment, a side of the lower sealing member may be inclined, and a cross-sectional area of the lower sealing member may be larger toward the substrate.

In an embodiment, an inner surface of the lower sealing member may be disposed apart from the semiconductor chip and may contact a non-conductive film fillet of the non-conductive film.

In an embodiment, the lower sealing member may be detachable from the upper sealing member. The bonding head may include a support plate and the sealing member may be disposed to completely surround the circumferential surface of the bonding head formed by the support plate.

In an embodiment, the upper sealing member may include an elasticity member. In an embodiment, a cross-sectional area of the elasticity member may decrease toward the lower sealing member.

In an embodiment, the upper sealing member may include a space having a fluid or a vacuum therein. In an embodiment, the upper sealing member may include a sealing member sealing the fluid or the vacuum in the space.

In an embodiment, the fluid or the vacuum in the space of the upper sealing member may be supplied from an external control device. In an embodiment, a protection layer may be disposed on at least a portion of a side of the sealing member. In an embodiment, a protection layer may be disposed on a lower surface of the bonding head.

A semiconductor chip bonding device according to an embodiment of the present disclosure is a device for bonding a semiconductor chip on a substrate, which may include a substrate support supporting the substrate, a bonding head including a support plate supporting the semiconductor chip, and a first penetration hole disposed penetrating the support plate and securing the semiconductor chip, and a sealing member surrounding a circumferential surface of the support plate and extending in a first direction from the bonding head toward the substrate, and comprising a lower sealing member movable in a first direction independent of the bonding head.

In an embodiment, the sealing member may include an upper sealing member having a space including a fluid or a vacuum and accommodating a portion of the lower sealing member, wherein the upper sealing member may include a sealing member disposed between an inner surface of the upper sealing member and an outer surface of the portion of the lower sealing member and sealing the fluid or the vacuum in the space. In an embodiment, the upper sealing member includes a second penetration hole that may be implemented independently from the first penetration hole, wherein the second penetration hole may be connected to the space in the upper sealing member.

A semiconductor chip bonding device according to an embodiment of the present disclosure is a device for bonding a semiconductor chip on a substrate, which may include a substrate support supporting the substrate, a bonding head including a support plate supporting the semiconductor chip, and a first penetration hole disposed penetrating the support plate and securing the semiconductor chip, a sealing member completely surrounding a circumferential surface of the support plate and extending in a first direction from the support plate toward the substrate, and a protection layer disposed on at least a portion of a lower surface of the support plate and an inner surface of the sealing member, wherein the sealing member may include an upper sealing member including a space accommodating an elasticity member and at least a portion of a lower sealing member extending in a first direction and movable in the first direction independent of the bonding head. In an embodiment, a height of the lower sealing member may be in a range of about 50 to 120 μm.

According to an embodiment of the present disclosure, a semiconductor chip bonding device may include a sealing member movable in a direction away from the substrate, so that a non-conductive film fillet may be formed in a certain shape.

### BRIEF DESCRIPTION OF THE DRAWINGS

FIG. 1A illustrates a semiconductor chip bonding device according to an embodiment of the present disclosure.

FIG. 1B and FIG. 1C are enlarged views of a P1 region of FIG. 1A.

FIG. 2 illustrates a semiconductor chip bonding device according to an embodiment of the present disclosure.

FIG. 3A illustrates a semiconductor chip bonding device according to an embodiment of the present disclosure.

FIG. 3B is an enlarged view of a P2 region of FIG. 3A.

FIG. 4A illustrates a semiconductor chip bonding device according to an embodiment of the present disclosure.

FIG. 4B, FIG. 4C, and FIG. 4D are enlarged views of a P3 region of FIG. 4A.

FIG. 5A illustrates a semiconductor chip bonding device according to an embodiment of the present disclosure.

FIG. 5B is an enlarged view of a P4 region of FIG. 5A.

FIG. 6A illustrates a semiconductor chip bonding device according to an embodiment of the present disclosure.

FIG. 6B is an enlarged view of a P5 region of FIG. 6A.

FIG. 7A, FIG. 7B, FIG. 7C, FIG. 7D, and FIG. 7E illustrate a semiconductor chip bonding method using a semiconductor chip bonding device according to an embodiment of the present disclosure.

### DETAILED DESCRIPTION

The present disclosure will be described in detail hereinafter with reference to the accompanying drawings, in which embodiments of the present disclosure are shown. As those skilled in the art would realize, embodiments may be modified in various different ways, all without departing from the spirit or scope of the present disclosure.

The drawings and description are to be regarded as illustrative in nature and not restrictive. Like reference numerals designate like elements throughout the specification.

A size and thickness of each constituent element in the drawings may be arbitrarily illustrated for better understanding and ease of description, and embodiments are not limited thereto. In the drawings, the thickness of layers, films, plates and regions may be exaggerated for clarity. In the drawings, the thickness of some layers and regions may be exaggerated for ease of description.

It will be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, embodiments will be described in detail so that those skilled in the art may easily practice the present disclosure. However, the present disclosure may be implemented in various different forms, and is not limited to embodiments described herein.

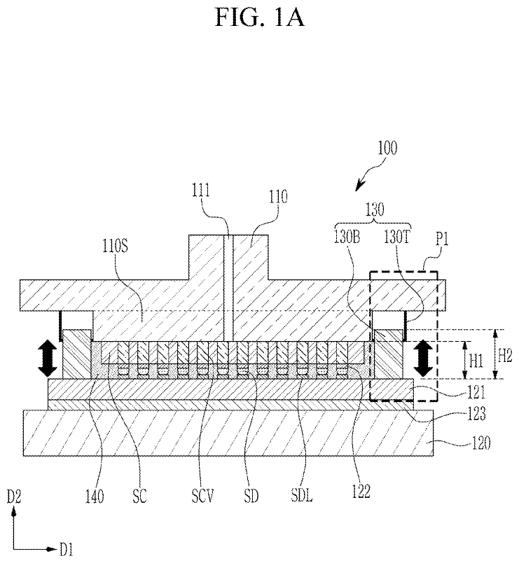

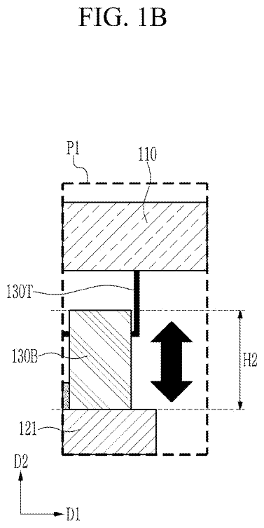

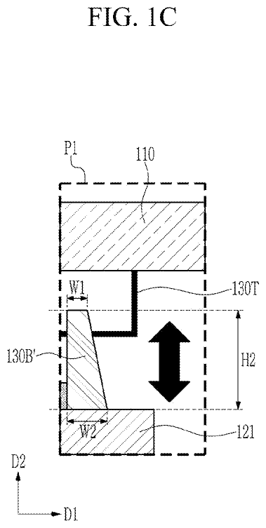

FIG. 1A illustrates a semiconductor chip bonding device according to an embodiment of the present disclosure, and FIG. 1B and FIG. 1C are enlarged views of a P1 region P1 of FIG. 1A.

Referring to FIG. 1A, a semiconductor chip bonding device 100 may be a device for bonding a semiconductor chip on a substrate or bonding semiconductor chips stacked on a substrate to each other in a packaging process, for example, for manufacturing a high bandwidth memory (HBM). That is, the semiconductor chip bonding device 100 according to an embodiment may be used in a multi-chip stack bonding process. The semiconductor chip(s) may be bonded to a substrate or another semiconductor chip using a non-conductive film (NCF) and solder.

In an embodiment, the semiconductor chip bonding device 100 may include a bonding head 110, a substrate support 120, and a sealing member 130. The semiconductor chip bonding device 100 may include a bonding head 110, the substrate support 120, and the sealing member 130 disposed spaced apart above the substrate support 120, surrounding the outer circumferential surface of the support plate 110S in the bonding head 110, extending in the direction of the substrate support 120, and is movable. The substrate support 120 may support a substrate 121. The bonding head 110 may be disposed on a semiconductor chip SC. Accordingly, the substrate 121 may be disposed below the semiconductor chip SC. The sealing member 130 may include a movable member, so that when in contact with the substrate 121, the movable member of the sealing member 130 may move relative to the bonding head 110 in the direction away from the substrate 121, such as in a first direction D2. As illustrated, the first direction D2 may be a vertical direction, perpendicular to a second direction D1. The second direction D1 may be a horizontal direction, which may be parallel to an upper surface of substrate support 120.

The first direction D2 may be a direction perpendicular to an upper surface of the substrate support 120, and may mean a direction in which the sealing member 130 extends from the substrate 121. For example, the sealing member 130 may be perpendicular to the substrate 121.

The bonding head 110 may include the support plate 110S. The support plate 110S may support and press the semiconductor chip SC on to the substrate support 120. The semiconductor chip SC may be thermally pressed toward the substrate 121. Accordingly, the bonding head 110 may stack the semiconductor chips SC on the substrate 121 to form a multi-chip stack.

The bonding head 110 may include a first penetration hole 111. The first penetration hole 111 may extend through the support plate 110S. The first penetration hole 111 may be used to apply a vacuum pressure securing the semiconductor chip SC to the bonding head 110.

In an embodiment, the bonding head 110 may include a driver that may drive the bonding head 110. The driver may be a member attached to the bonding head 110, which may control the semiconductor chip SC to be pressed and stacked with the substrate 121 or another semiconductor chip.

In an embodiment, the bonding head 110 may include a heater. The heater may supply heat. The bonding head 110 including the heater may supply heat while pressing the semiconductor chip SC to the substrate 121. The heater may have, for example, a rectangular plate shape. As a non-limiting example, the heater may be a ceramic heater including an electric resistance heating wire.

In an embodiment, the bonding head 110 may include the support plate 110S. The support plate 110S may have a column shape such as a cylindrical column or a rectangular column. For example, the support plate 110S may be a rectangular column having four sides. In an embodiment, the support plate 110S may be made of an oxidized material. For example, the support plate 110S may be made of a material such as aluminum oxide (Al₂O₃).

The substrate support 120 may surround an external circumferential surface of the support plate 110S. The substrate support 120 may be disposed away from the support plate 110S in the first direction D2.

The substrate support 120 may be disposed under the bonding head 110. The substrate 121 may be disposed on the upper surface of the substrate support 120.

In an embodiment, the substrate support 120 may be a member for supporting the substrate 121. The substrate support 120 may prevent the substrate 121 from being bent by heat. The substrate support 120 may include, for example, a heat-resistant material such as glass, silicon (Si), or ceramic.

The substrate 121 may be a member on which the semiconductor chip SC is stacked. As a non-limiting example, the substrate 121 may be a member such as a carrier substrate, a printed circuit board, or a lead frame. A bonding device according to an embodiment may be a bonding device for bonding semiconductor chips in a process of manufacturing a wafer level package. When a semiconductor chip bonding process is performed at the wafer level, the substrate 121 may include a wafer, and the substrate 121 shown in the drawings may be seen as illustrating only the substrate 121 in a single package.

In an embodiment, an adhesive layer 123 may be disposed between the substrate 121 and a substrate support 120. The adhesive layer 123 may be a member contacting the substrate 121 and the substrate support 120. The adhesive layer 123 may be, for example, a glue layer.

The sealing member 130 may include an upper sealing member 130T and a lower sealing member 130B. The upper sealing member 130T may be disposed above the lower sealing member 130B.

Specifically, the sealing member 130 may include an upper sealing member 130T accommodating at least a portion of the lower sealing member 130B. The upper sealing member 130T may support at least a portion of the lower sealing member 130B. The lower sealing member 130B may be a member disposed on a side of the semiconductor chip SC in the second direction D2. The lower sealing member 130B may be a member disposed apart from the side of the semiconductor chip SC in the second direction D2. The sealing member 130 including the upper sealing member 130T and the lower sealing member 130B may be movable to and away from the substrate support 120. The upper sealing member 130T may move relative to the lower sealing member 130B.

In an embodiment, the upper sealing member 130T is a member capable of accommodating at least a portion of the lower sealing member 130B. Specifically, the upper sealing member 130T may include a space in which the lower sealing member 130B may be accommodated when the upper sealing member 130T is vertically moved toward the substrate support 120. In a case that the sealing member 130 is moved toward the substrate support 120 and the lower sealing member 130B contacts the substrate 121, the upper sealing member 130T may continue to move toward the substrate support 120 and the lower sealing member 130B may be increasingly accommodated into the upper sealing member 130T.

In an embodiment, the lower sealing member 130B may be disposed parallel to the first direction D2 in which the semiconductor chips SC are stacked. Specifically, when the lower sealing member 130B contacts with the substrate 121 in the process of stacking the semiconductor chip SC on the substrate 121, even if the bonding head 110 is pressed, the lower sealing member 130B may move in the first direction D2 opposite to the pressing direction. When the lower sealing member 130B contacts with the substrate 121 in the process of stacking the semiconductor chip SC on the substrate 121, the bonding head 110 may be further pressed, and the lower sealing member 130B may be increasingly accommodated into the upper sealing member 130T.

The lower sealing member 130B may be disposed in contact with the substrate 121 during the process of the bonding head 110 being pressed, which may reduce or minimize damage to the substrate 121 and prevent excessive extrusion of a non-conductive film to the outside. The extruded non-conductive film may be referred to as a non-conductive film fillet 140.

In an embodiment, as a non-limiting example, the lower sealing member 130B may be formed of a material such as metal, ceramic, or rubber. The material of the lower sealing member 130B is not limited to the materials described herein, and various types of materials capable of reducing or minimizing damage to the substrate 121 may be used.

In an embodiment, the lower sealing member 130B may be a member detachable from the upper sealing member 130T. For example, in a case that the lower sealing member 130B is damaged by friction with the substrate 121, the lower sealing member 130B may be detached and replaced. In an embodiment, the lower sealing member 130B may be a consumable component.

In an embodiment, the sealing member 130 may be disposed to completely surround the external circumferential surface of the support plate 110S of the bonding head 110. For example, the sealing member 130 may be disposed to completely surround the external circumferential surface of four surfaces of the support plate 110S of the bonding head 110. As the sealing member 130 may be disposed to completely surround the external circumferential surface of the support plate 110S, it may be possible to control an extrusion of the non-conductive film. As the sealing member 130 may be disposed to completely surround the external circumferential surface of the support plate 110S, it may be possible to control an extrusion of the non-conductive film to form a non-conductive film fillet 140 having a desired shape.

The non-conductive film may be a member for bonding the semiconductor chip SC and the substrate 121, wherein a solder bump SD and a connection pad SDL of the semiconductor chip SC may be bonded to a pad 122 of the substrate 121, and the semiconductor chip SC may be mounted on the substrate 121. The solder bump SD and the connection pad SDL may be electrically connected, within the non-conductive film, to other stacked semiconductor chips through a semiconductor chip through via SCV.

The non-conductive film may be melted during the thermal compression bonding process to have fluidity. The non-conductive film may serve as an adhesive for bonding the semiconductor chip SC to the substrate 121 or bonding the semiconductor chip SC to another semiconductor chip.

The non-conductive film may reduce or prevent the substrate 121 from being bent due to a difference in a coefficient of thermal expansion (CTE) between the semiconductor chip SC and the substrate 121 during a bonding process. Specifically, the non-conductive film may reinforce a gap between the semiconductor chip SC and the substrate 121 by including, for example, an epoxy material. More specifically, the non-conductive film may function as a filler disposed in a space between the solder bumps SD. The non-conductive film may fill the space between the solder bumps SD. That is, the non-conductive film may be a filler disposed between the solder bumps SD and between the semiconductor chip SC and the substrate 121.

In an embodiment, an extruded portion of the non-conductive film, which may be a non-conductive film fillet 140, may be disposed in contact with an inner surface of the lower sealing member 130B. Specifically, when the non-conductive film is thermally pressed to the substrate 121, a first portion of the lower sealing member 130B may move into an accommodating space of the upper sealing member 130A, while the lower sealing member 130B is disposed in contact with the substrate 121 so that the non-conductive film may not be excessively extruded from the gap between the semiconductor chip SC and the substrate 121 and a shape of the non-conductive film fillet 140 may be controlled. The non-conductive film fillet 140 formed of an extruded portion of the non-conductive film may have a shape according to the lower sealing member 130B.

More specifically, the lower sealing member 130B may control an extent of the non-conductive film fillet 140 so that a cutting process may not be needed and a plurality of semiconductor chips and associated non-conductive film fillets 140 having a same size may be stacked. The lower sealing member 130B may prevent excessive extrusion of the non-conductive film from the gap between the semiconductor chip SC and the substrate 121. In an embodiment, an extruded portion of the non-conductive film forming a non-conductive film fillet 140 may be disposed in a space between the semiconductor chip SC and the lower sealing member 130B. The non-conductive film fillet 140 in the space between the semiconductor chip SC and the lower sealing member 130B may have an upper surface that is co-planar with an upper surface of the semiconductor chip SC.

In an embodiment, a height of the lower sealing member 130B may be about 1.2 times greater than the height of the semiconductor chip SC and the non-conductive film disposed below the semiconductor chip SC.

Specifically, the height of the lower sealing member 130B may be equal to or greater than about 1.2 times a sum of the heights of the semiconductor chip SC and the non-conductive film disposed below the semiconductor chip SC. The height of the lower sealing member 130B may be equal to or greater than about 1.2 times a combined height of the semiconductor chip SC and the non-conductive film disposed below the semiconductor chip SC.

In an embodiment, the height of the lower sealing member 130B may be in a range of about 50 to 120 micrometers (μm). More particularly, the height of the lower sealing member 130B may be in a range of about 60 to 120 μm.

The height H2 of the lower sealing member 130B may have a value greater than the sum of the semiconductor chip SC and the non-conductive film disposed below the semiconductor chip SC. The lower sealing member 130B may be moved in an opposite direction −D2 of the first direction D2 and away from the semiconductor chip SC. A second semiconductor chip may be mounted on the bonding head 110. The lower sealing member 130B may have a lower surface disposed below a bottom surface of the second semiconductor chip. As the bonding head 110 is moved in the first direction toward the semiconductor chip SC, the lower surface of the lower sealing member 130B may be disposed at a position lower than a top of the semiconductor chip SC, thereby preventing the non-conductive film fillet 140 extruded from the non-conductive film from being exposed to the outside. Thus, the lower sealing member 130B may vertically move in the first direction D2 and the second semiconductor chip may be bonded to the semiconductor chip SC.

Referring to FIG. 1B, according to an embodiment of the present disclosure, the lower sealing member 130B may be accommodated in at least a portion of the upper sealing member 130T. Specifically, when the lower sealing member 130B is in contact with the substrate 121, the upper sealing member 130T may be pressed toward the substrate 121 and the lower sealing member 130B may be accommodated in a region of the upper sealing member 130T, reducing or minimizing damage to the substrate 121.

More specifically, the lower sealing member 130B in contact with the substrate 121 and having a portion accommodated in the upper sealing member 130T may serve to reduce or prevent the non-conductive film fillet 140 from being exposed. The lower sealing member 130B may serve to control a shape of the non-conductive film fillet 140 extruded from the non-conductive film disposed between the semiconductor chip SC and the substrate 121.

In an embodiments, the lower sealing member 130B may have a right trapezoidal shape, hereinafter referred to a trapezoidal lower sealing member. The shape of the lower sealing member 130B is not limited, and other shapes may be possible.

Referring to FIG. 1C, in an embodiment, a side of the trapezoidal lower sealing member 130B′ may have an inclination of a predetermined angle. A cross-sectional area of the trapezoidal lower sealing member 130B′ may become gradually larger approaching the substrate 121.

Specifically, a side of the trapezoidal lower sealing member 130B′ may be inclined at a predetermined angle, and another side may be disposed parallel to the first direction D2. More specifically, an upper width W1 of the trapezoidal lower sealing member 130B′ may be narrower than a lower width W2 of the trapezoidal lower sealing member 130B′.

A side disposed parallel to the first direction D2 may have a height at least that of the non-conductive film fillet 140 formed of the non-conductive film, and the non-conductive film fillet 140 of the non-conductive film may be controlled to be stacked uniformly when stacking the semiconductor chips SC.

An inclined side of the trapezoidal lower sealing member 130B′ may have a predetermined angle. The inclined side of the trapezoidal lower sealing member 130B′ may be increasingly distant from the semiconductor chip SC toward the substrate.

As a cross-sectional area of the trapezoidal lower sealing member 130B′ gradually becomes larger closer to the substrate 121, when the trapezoidal lower sealing member 130B′ is spaced apart from the substrate 121, a weight of the trapezoidal lower sealing member 130B′ may move the trapezoidal lower sealing member 130B′ downward. Further, a portion of the trapezoidal lower sealing member 130B′ may move into the accommodating space of the upper sealing member 130T when the trapezoidal lower sealing member 130B′ is in contact with the substrate 121.

In an embodiment, the lower width W2 of the trapezoidal lower sealing member 130B′ may have a wider width than a lower exterior side of the upper sealing member 130T. FIG. 1C illustrates that the upper width W1 of the trapezoidal lower sealing member 130B′ may be disposed within the upper sealing member 130T, but this is not intended to limit the present disclosure.

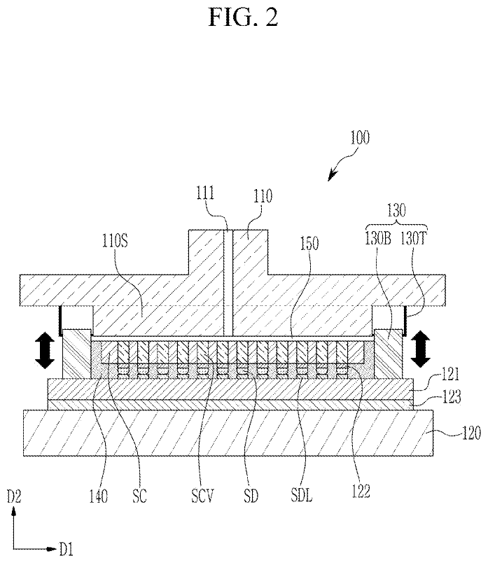

FIG. 2 illustrates the semiconductor chip bonding device 100 according to an embodiment of the present disclosure.

Referring to FIG. 2, in an embodiment, a protection layer 150 may be disposed on a lower surface of the support plate 110S. The protection layer 150 may be disposed on a member that may be touched by the non-conductive film. The protection layer 150 may reduce or prevent the semiconductor chip bonding device 100 from being contaminated by a material such as a non-conductive film.

In an embodiment, the protection layer 150 may be disposed on at least a portion of an inner side of the sealing member 130. Specifically, the protection layer 150 may be disposed on an inner side of the lower sealing member 130B of the sealing member 130.

The protection layer 150 disposed on the lower surface of the support plate 110S and contacting a side of the lower sealing member 130B may be applied integrally so as not to interfere with the motion of the lower sealing member 130B, or may be applied separately on the lower surface of the support plate 110S and on the sealing member 130.

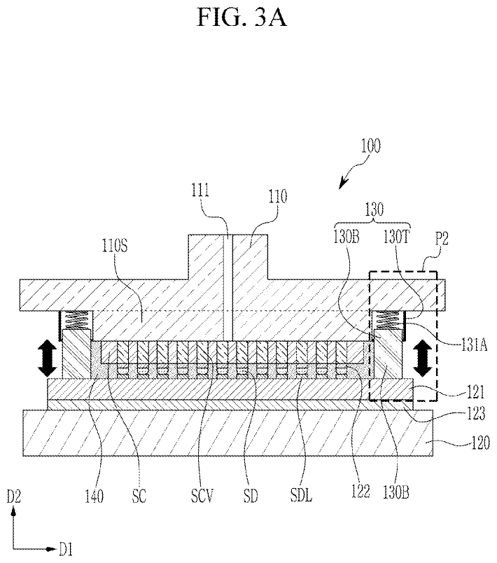

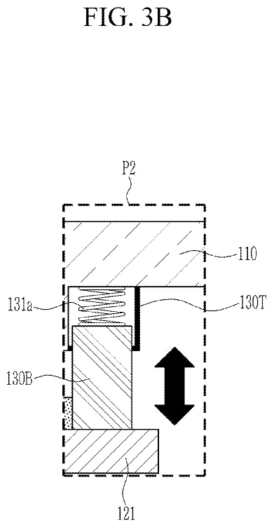

FIG. 3A illustrates a semiconductor chip bonding device according to an embodiment of the present disclosure, and FIG. 3B is an enlarged view of a P2 region of FIG. 3A.

Referring to FIG. 3A and FIG. 3B, in an embodiment, the upper sealing member 130T may include an elasticity member 131a. The elasticity member 131a may be a member for applying an elastic force. The elasticity member 131a may be, for example, a spring member as shown in FIG. 3A. Before the lower sealing member 130B contacts the substrate 121, the spring member may be in a tensioned state by the weight of the lower sealing member 130B without additional pressure being applied. When the lower sealing member 130B contacts the substrate 121, a compressive stress may be applied to the spring member. Thereafter, when the semiconductor chip SC is bonded and the lower sealing member 130B is separated from the substrate 121, the spring member may return to a tensioned state with the weight of the lower sealing member 130B applying a restoring force.

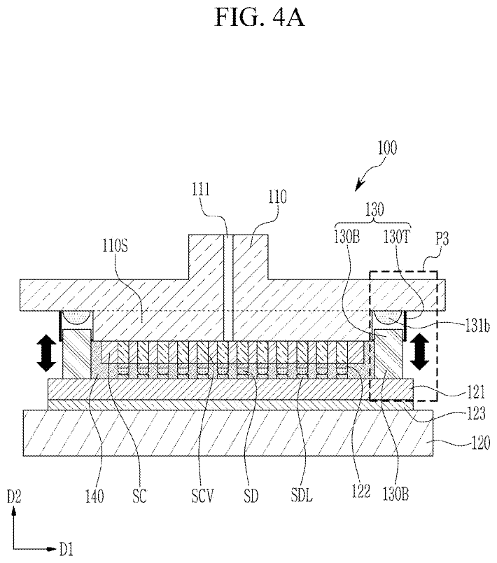

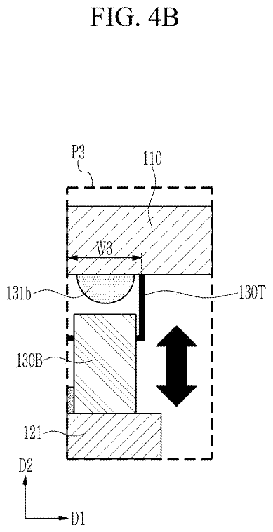

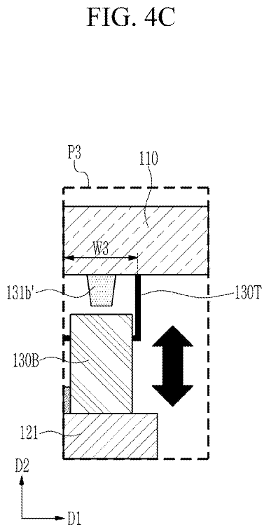

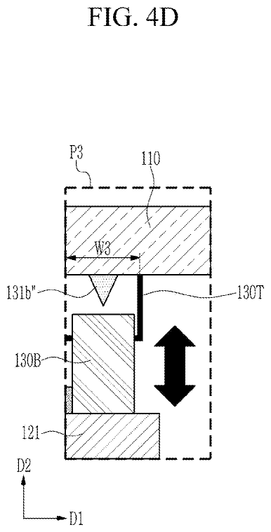

FIG. 4A illustrates a semiconductor chip bonding device according to an embodiment of the present disclosure, and FIG. 4B, FIG. 4C, and FIG. 4D are enlarged views of a P3 region of FIG. 4A.

Referring to FIG. 4A, in an embodiment, an elastic body 131b may be disposed on the upper sealing member 130T. The elastic body 131b may be disposed within the upper sealing member 130T and disposed toward and upper surface of the lower sealing member 130B. The elastic body 131b may be an object having elasticity. Specifically, the elastic body 131b may have a restoring force, the shape of the elastic body 131b may be deformed by the external force when an external force is applied to the elastic body 131b, and the shape of the elastic body 131b may be restored when the external force is removed.

Referring to FIG. 4B, in an embodiment, a cross-sectional area of the elastic body 131b may gradually decrease toward the lower sealing member 130B. Specifically, it can be seen that the width of the elastic body 131b decreases in a downward direction as compared to the width W3 of the elastic body 131b and an upper surface thereof.

As such, since the elastic body 131b has a shape in which the width decreases downward, an elasticity and a restoring force can be secured.

Referring to FIG. 4C and FIG. 4D, elastic bodies 131b′ and 131b″ may gradually decrease in area toward the lower sealing member 130B.

The elastic bodies 131b′ and 131b″ may have various shapes. Specifically, the elastic bodies 131b′ and 131b″ may have a trapezoid shape as shown in FIG. 4C or may have a triangle shape as shown in FIG. 4D. This does not limit the present disclosure.

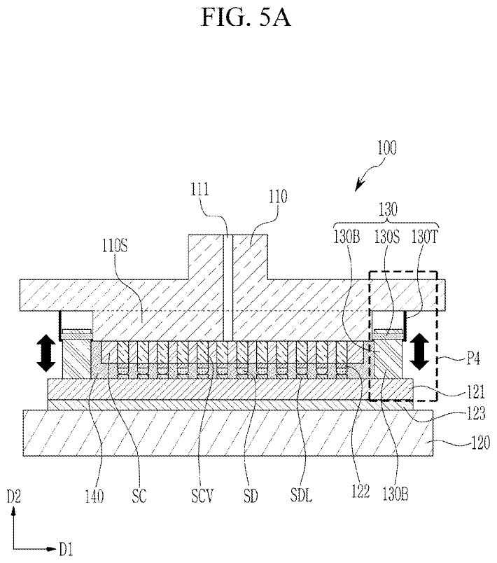

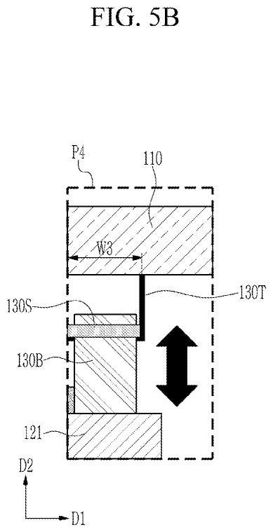

FIG. 5A illustrates the semiconductor chip bonding device 100 according to an embodiment of the present disclosure, and FIG. 5B is an enlarged view of a P4 region of FIG. 5A.

Referring to FIG. 5A and FIG. 5B, the upper sealing member 130T may be filled with a fluid or a vacuum. Specifically, the upper sealing member 130T may maintain a state in which the upper sealing member 130T may include a space filled with a fluid or a vacuum.

When the sealing member 130 is spaced apart from the substrate 121, the space of the upper sealing member 130T may be filled with the fluid or the vacuum, and the lower sealing member 130B may be pushed in a direction toward the substrate 121. When the lower sealing member 130B is in contact with the substrate 121 and the upper sealing member 130T is being pressed toward the substrate 121, the lower sealing member 130B may be maintained in contact with the substrate 121, and the lower sealing member 130B may be pushed into the space of the upper sealing member 130T. The lower sealing member 130B pushed into the upper sealing member 130T may displace the fluid or the vacuum from the space.

Thereafter, the lower sealing member 130B may be fixed relative to the substrate 121, with a position fixed by a hydraulic lock provided by the fluid or vacuum in the space of the upper sealing member 130T. As such, the lower sealing member 130B to serve as a preventing member to reduce or prevent exposure of the non-conductive film. A hydraulic system for moving and fixing the lower sealing member 130B may be implemented without a separate fixing member.

In an embodiment, the upper sealing member 130T may include a sealing member 130S that may prevent leakage of the fluid or the vacuum. The sealing member 130S may seal the fluid or the vacuum in the space of the upper sealing member 130T. Specifically, the sealing member 130S may be disposed below the upper sealing member 130T. For example, the sealing member 130S may be disposed at a lower part of the upper sealing member 130T. This is a non-limiting example, and the sealing member 130S may be disposed in various positions.

The sealing member 130S may be disposed in the upper sealing member 130T and may reduce or prevent leakage of the fluid or the vacuum, thereby preventing the formation of a gap that may occur if the lower sealing member 130B moves away from the substrate 121 in a bonding process. For example, the sealing member 130S may maintain a fluid or vacuum state and enable the application of a hydraulic pressure such that the lower sealing member 130B may be moved using a similar principle to that of a piston.

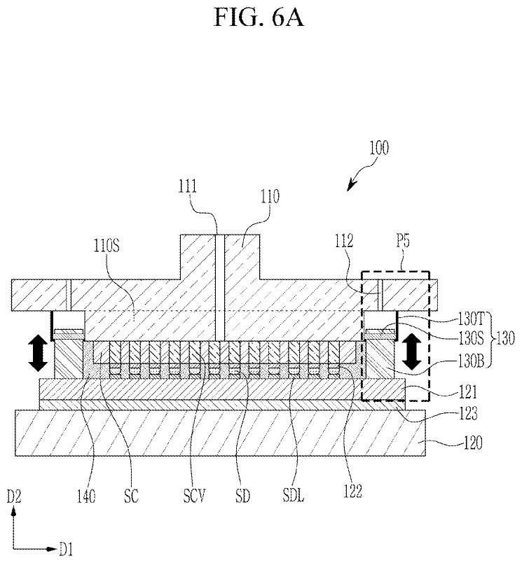

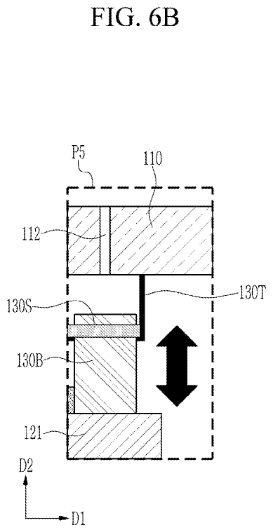

FIG. 6A illustrates the semiconductor chip bonding device 100 according to an embodiment of the present disclosure, and FIG. 6B is an enlarged view of a P5 region of FIG. 6A.

Referring to FIG. 6A and FIG. 6B, in an embodiment, the fluid or vacuum in the upper sealing member 130T may be supplied from an external control device. Specifically, the upper sealing member 130T may allow fluid or vacuum to flow through a second penetration hole 112.

The second penetration hole 112 may be supplied with fluid or vacuum from a separate external control device provided outside, and may control the movement of the lower sealing member 130B.

In an embodiment, the first penetration hole 111 and the second penetration hole 112 of the bonding head 110 may be provided independently. Specifically, a device for providing a fluid or a vacuum may independently control the flow of the fluid or the vacuum to the first penetration hole 111 to secure the semiconductor chip SC in a first circuit and to the upper sealing member 130T to control the lower sealing member 130B in a second circuit. For example, the first circuit and the second circuit may share a pump or have different pumps for controlling the flow of the fluid or the vacuum. The first circuit and the second circuit may share a reservoir of fluid or gas, or may have separate reservoirs.

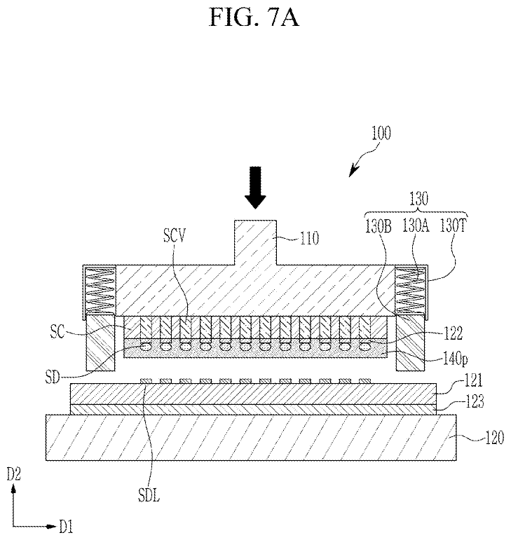

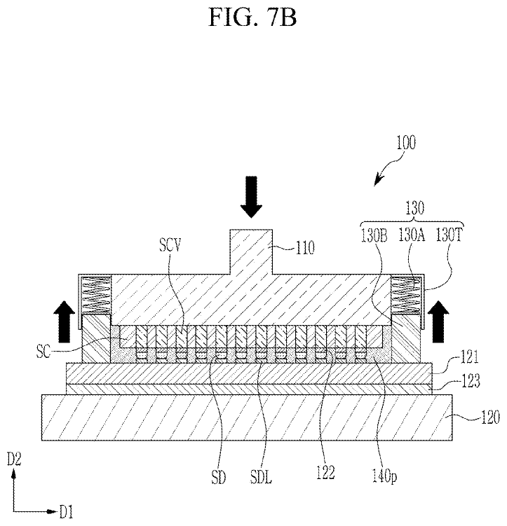

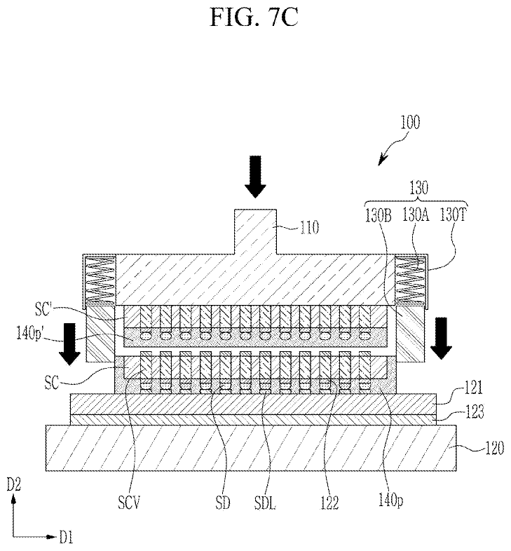

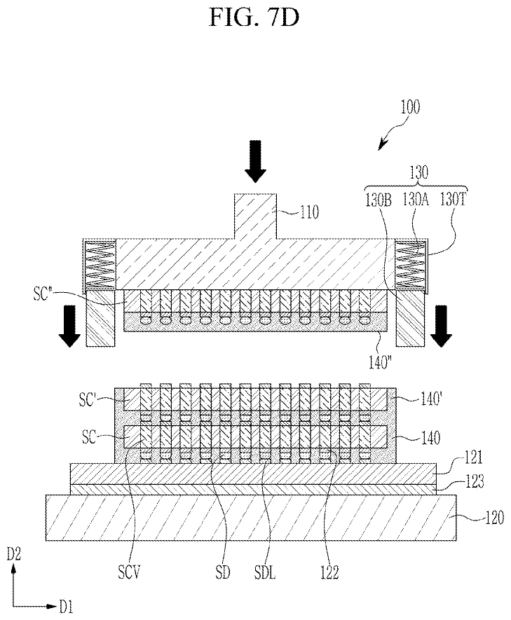

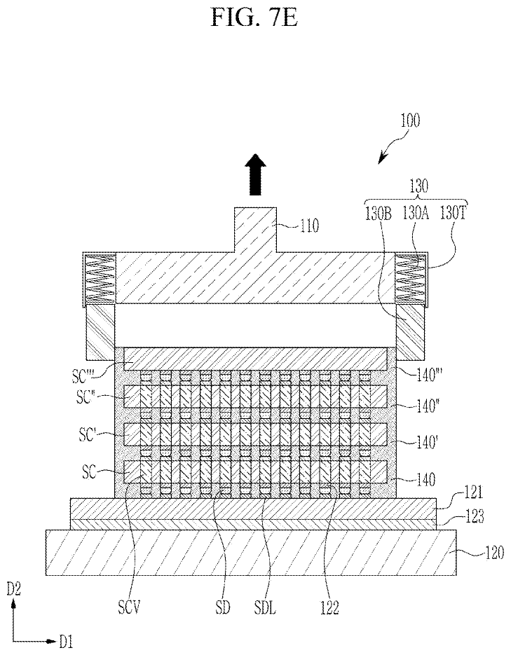

FIG. 7A, FIG. 7B, FIG. 7C, FIG. 7D, and FIG. 7E illustrate a semiconductor chip bonding method using the semiconductor chip bonding device 100 according to an embodiment of the present disclosure.

Referring to FIG. 7A, the semiconductor chip bonding method may include preparing a semiconductor chip SC having a non-conductive film 140p disposed on a surface of the bonding head 110. The substrate 121 may be prepared in a state below the non-conductive film 140p disposed on the lower surface of the semiconductor chip SC. The non-conductive film 140p may be coated on the lower surface of the semiconductor chip SC to have a thickness greater than a target thickness range for the non-conductive film 140p after contact with the substrate 121.

Referring to FIG. 7B, the non-conductive film 140p may be disposed on the substrate 121. The bonding head 110 and the semiconductor chip SC may be moved toward the substrate 121, and the non-conductive film 140p may be disposed on the substrate 121 so that the semiconductor chip SC and the substrate 121 may be electrically connected. Specifically, the semiconductor chip SC and the substrate 121 may be electrically connected by connecting the solder bump SD to the connection pad SDL disposed on the substrate 121.

The lower sealing member 130B may move in the first direction D2 opposite to the opposite direction −D2 to the first direction D2 relative to the bonding head 110, which is the pressing direction of the bonding head 110 while being in contact with the substrate 121. The lower sealing member 130B may move toward the upper sealing member 130T while in contact with the substrate 121 and while the bonding head 110 and the semiconductor chip SC are moved toward the substrate 121. The lower sealing member 130B may remain in contact with the substrate 121 as the bonding head 110 is pressed toward the substrate 121. The lower sealing member 130B may prevent the non-conductive film 140p from being exposed in a direction opposite to the semiconductor chip SC. The lower sealing member 130B may prevent the non-conductive film 140p from being freely extruded from between the semiconductor chip SC and the substrate 121. The lower sealing member 130B may control the non-conductive film 140p being extruded from between the semiconductor chip SC and the substrate 121.

In operation of electrically connecting the semiconductor chip SC and the substrate 121, the elastic force and an opposite restoring force may be applied by the elasticity member 131a disposed in the upper sealing member 130T. An extrusion of the non-conductive film 140p may be controlled to be disposed on the side of the lower sealing member 130B without being exposed to the outside. FIG. 7B illustrates a spring member as the elasticity member 131a in the upper sealing member 130T, but the present disclosure is not limited thereto, and a same principle can be applied even when the elastic body 131b, fluid, or hydraulic pressure is provided.

The bonding head 110 may secure the semiconductor chip SC having a non-conductive film disposed on a surface thereof, and the semiconductor chip SC may be disposed on the substrate 121. The bonding head 110 may secure the semiconductor chip SC, and the bonding head 110 and/or the substrate support 120 may be moved so that the semiconductor chip SC may be disposed on the substrate 121.

The semiconductor chip SC may include a die, a wiring layer, a through silicon via (TSV), a connection pad, and an adhesive layer. The wiring layer and the connection pad SDL may be disposed on at least one surface of the die. The wiring layer may include a wire pattern and an insulation layer. The TSV may pass through the die and be electrically connected to the wire pattern of the wiring layer and the connection pad SDL. In an embodiment, in the semiconductor chip SC, the solder bump SD may be disposed below the connection pad SDL.

The solder bump SD may be disposed on the connection pad SDL. The solder bump SD may electrically connect the TSV formed in the die and circuit structures. The semiconductor chip SC may cover members such as the solder bump SD and the connection pad SDL with the non-conductive film 140p, which may be an adhesive layer.

In an embodiment, the bonding head 110 may perform bonding by applying heat and pressure to the semiconductor chip SC. Bonding by applying heat and pressure to the semiconductor chip SC by the bonding head 110 may be performed by a thermal compression bonding (TCB) process. Through the TCB process, the non-conductive film may be melted to have fluidity. The non-conductive film may serve as an adhesive to bond the semiconductor chip SC to the substrate 121 or another semiconductor chip.

Referring to FIG. 7C, stacking an additional semiconductor chip SC′ on the semiconductor chip SC, which itself may be stacked on the substrate may be included. The semiconductor chip SC′ may be an upper chip, and the semiconductor chip SC may be a lower chip. The upper and lower chips may be connected using a TSV for CoW.

When a non-conductive film 140p′ of the additional semiconductor chip SC contacts the semiconductor chip SC and the semiconductor chip SC and the additional semiconductor chip SC′ are connected, the lower sealing member 130B may remain in a movable state toward in a direction opposite to the first direction D2, and the lowermost side of the lower sealing member 130B may be disposed at a position lower than the highest side of the semiconductor chip SC.

Specifically, as a lower surface of the lower sealing member 130B may be disposed at a position lower than the uppermost side of the semiconductor chip SC, the lower sealing member 130B may completely seal the additional semiconductor chip SC′, and the non-conductive film 140p′ disposed on a surface of the additional chip SC′ may be prevented from being exposed to the outside.

Referring to FIG. 7D and FIG. 7E, as in FIG. 7C, a plurality of semiconductor chips SC, SC′, SC″, SC″ may be stacked using the semiconductor chip bonding device 100 of the present disclosure. In an embodiment, it may be possible to manufacture a multi-chip stack including the stacked semiconductor chips SC, SC′, SC″, SC′″ in which the non-conductive film fillets 140, 140′, 140″, 140″ have a same size. The non-conductive film fillets 140, 140′, 140″, 140′ may have a same angle, for example, an angle perpendicular to an upper surface of the substrate 121. The non-conductive film fillets 140, 140′, 140″, 140′″ may form a vertical side of the multi-chip stack. In an embodiment, an additional cutting process for cutting the non-conductive film fillets 140, 140′, 140″, 140′″ may be omitted.

As such, referring to FIG. 7A, FIG. 7B, FIG. 7C, FIG. 7D, and FIG. 7E, one or more semiconductor chips may be bonded on a substrate around the semiconductor chip SC, and an additional semiconductor chips SC′ may be stacked on semiconductor chip SC. In addition, the sealing member 130 may enable a manufacture of a semiconductor package in which the size of a non-conductive film fillet formed of the non-conductive film may be controlled. Further, a separate cutting process for cutting the non-conductive film fillet may be omitted. A detailed description of the sealing member 130 may refer to the semiconductor chip bonding device 100 described herein. While embodiments of the present disclosure have been described with reference to the accompanying drawings, those skilled in the art will appreciate that may variations and modifications can be made without departing from the spirit and scope of the claims and their equivalents. Therefore, embodiments described above are to be regarded as illustrative in all respects and not restrictive.

### DESCRIPTION OF SYMBOLS

| | |
|---|---|
| 100: Semiconductor chip bonding device | |
| 110: Bonding head | 120: Substrate support |
| 121: Substrate | 130: Sealing member |
| 130T: Upper sealing member | 130B: Lower sealing member |
| 131a: Elasticity member | 131b, 131b′, 131b″: Elastic |
| | body |
| 140: Non-conductive film fillet | |

What is claimed is:

1. A semiconductor chip bonding device comprising:
a substrate support;
a bonding head moveable in a first direction toward the substrate support; and
a sealing member disposed on the bonding head and surrounding a circumferential surface of the bonding head and extending in the first direction from the bonding head toward the substrate support and movable in the first direction.

2. The semiconductor chip bonding device of claim 1, wherein:
the sealing member comprises:
an upper sealing member disposed on the bonding head; and
a lower sealing member extending from the upper sealing member and movable in the first direction independent of the upper sealing member,
wherein the upper sealing member accommodates and supports at least a portion of the lower sealing member.

3. The semiconductor chip bonding device of claim 2, wherein:
a height of the lower sealing member is at least about 1.2 times greater than a height of a semiconductor chip disposed on the bonding head and a non-conductive film disposed below the semiconductor chip.

4. The semiconductor chip bonding device of claim 2, wherein:
a height of the lower sealing member is in a range of about 50 to 120 micrometers.

5. The semiconductor chip bonding device of claim 2, wherein:
a side of the lower sealing member is inclined, and
a cross-sectional area of the lower sealing member is larger toward the substrate.

6. The semiconductor chip bonding device of claim 3, wherein:
an inner surface of the lower sealing member is disposed apart from the semiconductor chip and contacts a non-conductive film fillet of the non-conductive film.

7. The semiconductor chip bonding device of claim 2, wherein:
the lower sealing member is detachable from the upper sealing member.

8. The semiconductor chip bonding device of claim 1, wherein:
the bonding head comprises a support plate and the sealing member is disposed to completely surround the circumferential surface of the bonding head formed by the support plate.

9. The semiconductor chip bonding device of claim 2, wherein:
the upper sealing member includes an elasticity member.

10. The semiconductor chip bonding device of claim 9, wherein:
a cross-sectional area of the elasticity member decreases toward the lower sealing member.

11. The semiconductor chip bonding device of claim 2, wherein:
the upper sealing member includes a space having a fluid or a vacuum therein.

12. The semiconductor chip bonding device of claim 11, wherein:
the upper sealing member includes a sealing member sealing the fluid or the vacuum in the space.

13. The semiconductor chip bonding device of claim 11, wherein:
the fluid or the vacuum in the space of the upper sealing member is supplied from an external control device.

14. The semiconductor chip bonding device of claim 1, wherein:
a protection layer is disposed on at least a portion of a side of the sealing member.

15. The semiconductor chip bonding device of claim 1, wherein:
a protection layer is disposed on a lower surface of the bonding head.

16. A semiconductor chip bonding device for bonding a semiconductor chip on a substrate, comprising:
a substrate support supporting the substrate;
a bonding head including a support plate supporting the semiconductor chip, and a first penetration hole disposed penetrating the support plate and securing the semiconductor chip; and
a sealing member surrounding a circumferential surface of the support plate and extending in a first direction from the bonding head toward the substrate, and comprising a lower sealing member movable in the first direction independent of the bonding head.

17. The semiconductor chip bonding device of claim 16, wherein the sealing member further comprises an upper sealing member having a space including a fluid or a vacuum and accommodating a portion of the lower sealing member, wherein
the upper sealing member includes a sealing member disposed between an inner surface of the upper sealing member and an outer surface of the portion of the lower sealing member and sealing the fluid or the vacuum in the space.

18. The semiconductor chip bonding device of claim 17, wherein
the upper sealing member includes a second penetration hole implemented independently from the first penetration hole, wherein the second penetration hole is connected to the space in the upper sealing member.

19. A semiconductor chip bonding device for bonding a semiconductor chip on a substrate, comprising:
a substrate support supporting the substrate;
a bonding head including a support plate supporting the semiconductor chip, and a first penetration hole disposed penetrating the support plate and securing the semiconductor chip;
a sealing member completely surrounding a circumferential surface of the support plate and extending in a first direction from the support plate toward the substrate; and
a protection layer disposed on at least a portion of a lower surface of the support plate and an inner surface of the sealing member,
wherein the sealing member comprises an upper sealing member including a space accommodating an elasticity member and at least a portion of a lower sealing member extending in the first direction and movable in the first direction independent of the bonding head.

20. The semiconductor chip bonding device of claim 19, wherein:
a height of the lower sealing member is in a range of about 50 to 120 micrometers.
